(19) United States
(12) Patent Application Publication
(10) Pub. No.: US 2024/0085800 A1
(43) Pub. Date: Mar. 14, 2024

(54) PROJECTION EXPOSURE APPARATUS AND METHOD FOR DESIGNING A COMPONENT OF A PROJECTION EXPOSURE APPARATUS

(71) Applicant: Carl Zeiss SMT GmbH, Oberkochen (DE)

(72) Inventors: Thilo Pollak, Oberkochen (DE); Dietmar Duerr, Oberkochen (DE); Irina Schrezenmeier, Oberkochen (DE); Joerg Tschischgale, Oberkochen (DE); Matthias Manger, Oberkochen (DE); Andreas Beljakov, Oberkochen (DE); Stefan Baueregger, Oberkochen (DE); Alexander Ostendorf, Oberkochen (DE); Dieter Bader, Oberkochen (DE); Markus Raab, Oberkochen (DE); Bastian Keller, Oberkochen (DE)

(21) Appl. No.: 18/507,893

(22) Filed: Nov. 13, 2023

Related U.S. Application Data
(63) Continuation of application No. PCT/EP2022/063972, filed on May 24, 2022.

(30) Foreign Application Priority Data
May 27, 2021 (DE) 10 2021 205 368.8

(51) Int. Cl. G03F 7/00; G02B 5/08; G02B 5/09

(52) U.S. Cl. CPC G03F 7/70266; G02B 5/0891; G02B 5/09

(57) ABSTRACT

A component for a projection exposure apparatus for semiconductor lithography, comprises an optical element and an actuator, which are force-fittingly connected to each other. The actuator at least locally deforms the optical element. The actuator can be configured to minimize the loss in rigidity at the peripheries delimiting the actuator on the imaging quality. A method for designing a component of projection exposure apparatus is provided.

### CROSS-REFERENCE TO RELATED APPLICATIONS

The present application is a continuation of, and claims benefit under 35 USC 120 to, international application PCT/EP2022/063972, filed May 24, 2022, which claims benefit under 35 USC 119 of German Application No 10 2021 205 368.8, filed May 27, 2021. The entire disclosure of each these applications is incorporated by reference herein.

### FIELD

The disclosure relates to a component for a projection exposure apparatus for semiconductor lithography and to a method for designing the component, such as for minimizing undesirable effects of parasitic deformations caused by an actuator on the imaging quality of the projection exposure apparatus.

### BACKGROUND

In projection exposure apparatuses for semiconductor lithography, optical elements, such as lens elements and/or mirrors, are used for imaging a lithography mask, such as, for example, a phase mask, also known as a reticle, onto a semiconductor substrate, also known as a wafer.

In order to help achieve a high resolution especially of lithography optical units, EUV light having a wavelength of, for example, between 1 nm and 120 nm, such as in the region of 13.5 nm, has also been used for some years, in comparison with predecessor systems having typical wavelengths of 365 nm, 248 nm or 193 nm.

Some of the optical elements used in that case are manipulated, for example, mechanically in order to improve the imaging quality and in order to correct disturbances that occur during operation, wherein a distinction is drawn between a pure shift of the optical elements and a deformation of the optical elements.

In the case of deformable mirrors, actuators, for example in the form of an actuator matrix, are known to have been adhesively connected or bonded to the rear side of the mirrors to create a mechanical connection for a targeted deformation.

Actuator matrices which are embodied in the form of a quadrangular plate and comprise a plurality of interconnected actuator pads are known. The individual actuator pads typically have a quadrangular or triangular shape and comprise holes typically arranged at the corners or sides of the actuator pads. These can have the function that the actuator pads can be contacted to controllers. A physics-related loss of rigidity of the combination of the actuator with the optical element can occur at all peripheries of the actuator, that is to say at the outer edges of the plate of the actuator matrix and the peripheries of the holes, which loss results in parasitic deformations in the region of the peripheries during the actuation or for example due to different thermal expansions based on different coefficients of thermal expansion. This can negatively influence the imaging quality of the projection exposure apparatus.

Due to the scanning mode of operation of certain modern lithography systems, that is to say the movement of the phase mask underneath an illumination slit and a movement of the wafer in an opposite direction, aberrations, which can be caused by the parasitic deformations described, along the scanning direction can add up, which can makes the undesirable effect more pronounced.

SUMMARY

The present disclosure seeks to provide an improved component. The disclosure also seeks to provide a method for designing the component.

A component according to the disclosure for a projection exposure apparatus for semiconductor lithography comprises an optical element and an actuator. The optical element and the actuator are force-fittingly connected to each other, wherein the actuator is configured to at least locally deform the optical element. According to the disclosure, the actuator can be embodied such that the influence of the loss in rigidity at the peripheries delimiting the actuator on the imaging quality is minimized. The force-fitting connection between the actuator and the optical element, such as a mirror, can be brought about by an adhesive connection or bonding or by a releasable connection, such as a screw connection.

In a first embodiment of the disclosure, the actuator can be embodied in the form of an actuator matrix comprising at least two actuator pads. The actuator matrix typically comprises between 9 and 30 actuator pads.

In particular, the cumulative length of the peripheral sections of the actuator extending on an axis parallel to a scanning direction used in the projection exposure apparatus can be minimized. The scanning exposure method used in projection exposure apparatuses can mean that some optical effects of disturbances extending perpendicular to the scanning direction, such as parasitic deformations, are averaged out by the scanning operation and thus minimized.

Furthermore, the outer peripheries of the actuators can be aligned, at least in sections, at an angle to the scanning direction. As a result, the portion of the sections of the peripheries extending in the scanning direction which is summed through the scanning operation can be minimized.

In particular, the actuator can include a peripheral contour meandering around the scanning direction. The contour can be realized, for example, by a hexagonal shape of the actuator pads and by a shift of the actuator pads arranged in rows by half the width of an actuator pad, wherein protrusions of the actuator pads partially protrude into recesses of adjacent pads.

In addition, a straight peripheral structure of the actuator can be aligned at an angle to the scanning direction. This can mean that no more portions, which are aligned in the scanning direction, of the peripheries delimiting the actuator are present. However, it may be desirable to take into account a possible construction-type-related influence of the inclination of the actuator on the deformation effect of the actuator with respect to an optically effective surface.

In particular, holes for contacting the actuator pads formed in the actuator matrix can be designed such that the cumulative length of the edge sections of the holes extending on an axis parallel to a scanning direction used in the projection exposure apparatus is reduced.

This can be accomplished, for example, in that the area of at least some of the holes is minimized, as a result of which the cumulative overall length of the edges of all holes is reduced. The holes can be formed at the corners, the sides, within the effective surface of the actuator pad or in a combination of these positions. The size of the holes is defined by the space for contacting.

Furthermore, the holes can be arranged such that the number of the holes arranged on an axis extending parallel to the scanning direction is minimal. The parasitic aberration summed by the scanning movement thus becomes minimal. The number of the holes located on an axis can be reduced, for example, by an advantageous arrangement of the holes with respect to the actuator pads, as described further above.

In a further embodiment of the disclosure, the actuator pads can have a triangular, a rectangular or a hexagonal geometry. In addition to the geometry of the actuator pads, the number of the rows and columns of the actuator matrices formed by the actuator pads can also be freely selectable, with the result that for example matrices of three rows and three columns up to five rows and five columns or more are conceivable. Nor does the number of rows and columns need to be identical, and a matrix with four rows and six columns can thus also be formed.

In a further embodiment of the disclosure, the actuator can have a separately controllable section for correcting the loss in rigidity. It thereby can become possible to take into account the rigidity, which deviates in the region of the intermediate spaces, of the overall system composed of actuator pad and mirror material by correspondingly modified control of the section, as a result of which an undesired movement/deformation is counteracted and a resulting possible image error can be avoided.

In particular, the section can be formed as a peripheral actuator pad in an actuator pad arranged in the peripheral region of the actuator matrix and can be controllable independently of the second region of the actuator pad formed as a partial actuator pad and be configured for correcting the parasitic deformations caused by the loss in rigidity. Owing to the peripheral actuator pad, the deformation effect at the periphery can be increased in comparison with a non-divided actuator pad, as a result of which the loss in rigidity can be compensated.

A method according to the disclosure for designing a component of a projection exposure apparatus with an optical element and an actuator for minimizing the effects of parasitic deformations in the case of the deformation of the optical element caused by the actuator on the imaging quality of the projection exposure apparatus comprises the following method steps:
designing the actuator,
determining the parasitic deformations of the optical element caused by an actuation or by different coefficients of thermal expansion of the optical element and the actuator,
determining the parasitic aberrations on the basis of the parasitic deformations while taking into account the summing effect of a scanning exposure used in the projection exposure apparatus,
optimizing the actuator on the basis of the determined parasitic aberrations,
repeating at least some of the preceding process steps until the value for the parasitic aberration falls under a predetermined value.

The parasitic deformations can be determined for example by FEM simulations or on the optically effective surface of the optical element via an optical measuring technique. The parasitic aberrations can be determined by simulations based on the parasitic deformations or by measurements on the component level or in the overall system, that is to say in the projection exposure apparatus.

Furthermore, at least a part of a travel of the actuator can be used to correct the parasitic deformations. This self-correction, as it is known, can mean that the errors can be compensated at the site where they occur.

In addition, the projection exposure apparatus can comprise a mechanism for optimizing the imaging quality can be taken into account when determining the resulting parasitic aberrations.

In particular, the mechanism can include manipulators for positioning or deforming further optical elements of the projection exposure apparatus. Typically, almost all optical elements of the projection exposure apparatus are manipulable, and therefore a large selection of additional correction mechanisms may be available.

Furthermore, one approach can involve an algorithm based on simulations for the prediction of the imaging quality while taking into account a multiplicity of influence parameters and the determination of the travels of the manipulators therefor.

### BRIEF DESCRIPTION OF THE DRAWINGS

Exemplary embodiments and variants of the disclosure are explained in greater detail below with reference to the drawing. In the figures,

FIG. 1 schematically shows a meridional section of a projection exposure apparatus for EUV projection lithography,

FIG. 2 schematically shows a meridional section of a further projection exposure apparatus for DUV projection lithography,

FIGS. 3A-3B show a component known from the prior art and a wavefront illustration,

FIGS. 4A-4B show a first embodiment of a component according to the disclosure and a wavefront illustration,

FIGS. 5A-5F show detail views of a component according to the disclosure,

FIG. 6 shows a further embodiment of a component according to the disclosure,

FIG. 7 shows a detail view of the disclosure, and

FIG. 8 shows a flowchart relating to a method for designing a component according to the disclosure.

### EXEMPLARY EMBODIMENTS

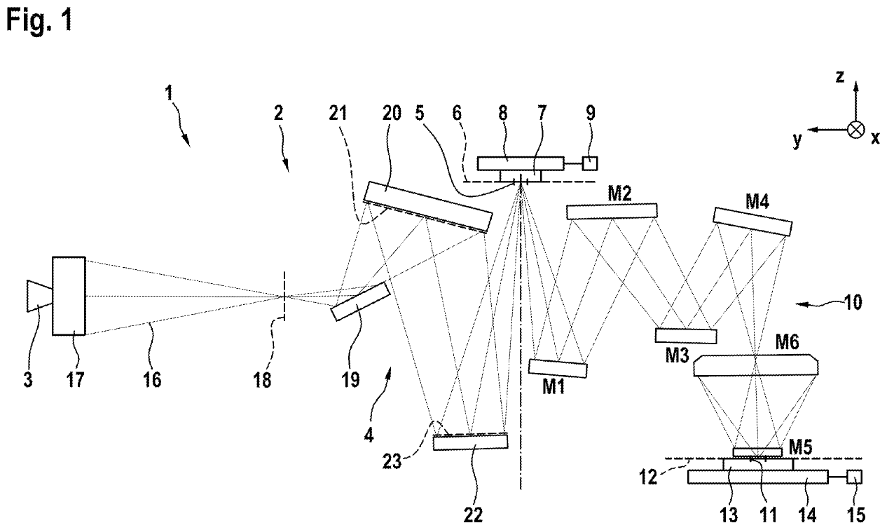

Certain integral parts of a microlithographic projection exposure apparatus 1 are described in exemplary fashion below initially with reference to FIG. 1. The description of the fundamental construction of the projection exposure apparatus 1 and the integral parts thereof is understood here to be non-limiting.

An embodiment of an illumination system 2 of the projection exposure apparatus 1 has, in addition to a radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, in particular in a scanning direction.

A Cartesian xyz-coordinate system is shown in FIG. 1 for explanation purposes. The x-direction runs perpendicular to the plane of the drawing into the latter. The y-direction runs horizontally and the z-direction runs vertically. The scanning direction runs along the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 runs parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y-direction. The displacement, on the one hand, of the reticle 7 by way of the reticle displacement drive 9 and, on the other hand, of the wafer 13 by way of the wafer displacement drive 15 can take place in such a way as to be synchronized with one another.

The radiation source 3 is an EUV radiation source. The radiation source 3 emits, in particular, EUV radiation 16, which is also referred to below as used radiation, illumination radiation or illumination light. In particular, the used radiation has a wavelength in the range between 5 nm and 30 nm. The radiation source 3 can be a plasma source, for example an LPP (laser produced plasma) source or a GDPP (gas discharge produced plasma) source. It can also be a synchrotron-based radiation source. The radiation source 3 can be a free electron laser (FEL).

The illumination radiation 16 emerging from the radiation source 3 is focused by a collector 17. The collector 17 may be a collector with one or with a plurality of ellipsoidal and/or hyperboloidal reflection surfaces. The illumination radiation 16 can impinge on the at least one reflection surface of the collector 17 with grazing incidence (GI), that is to say at angles of incidence of greater than 45°, or with normal incidence (NI), that is to say at angles of incidence of less than 45°. The collector 17 can be structured and/or coated, firstly, for optimizing its reflectivity for the used radiation and, secondly, for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect that goes beyond the purely deflecting effect. Alternatively or in addition, the deflection mirror 19 can be in the form of a spectral filter which separates a used light wavelength of the illumination radiation 16 from extraneous light with a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of the facets 21 by way of example.

The first facets 21 can be in the form of macroscopic facets, in particular as rectangular facets or as facets with an arcuate peripheral contour or a peripheral contour of part of a circle. The first facets 21 may be in the form of plane facets or alternatively as convexly or concavely curved facets.

As known for example from DE 10 2008 009 600 A1, the first facets 21 themselves may also be composed in each case of a multiplicity of individual mirrors, in particular a multiplicity of micromirrors. The first facet mirror 20 can in particular be formed as a microelectromechanical system (MEMS system). For details, reference is made to DE 10 2008 009 600 A1.

Between the collector 17 and the deflection mirror 19, the illumination radiation 16 travels horizontally, that is to say along the y-direction.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular, or hexagonal periphery, or alternatively be facets made up of micromirrors. In this regard, reference is likewise made to DE 10 2008 009 600 A1.

The second facets 23 can have plane or alternatively convexly or concavely curved reflection surfaces.

The illumination optical unit 4 consequently forms a doubly faceted system. This fundamental principle is also referred to as a fly's eye condenser (fly's eye integrator).

It can be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

The individual first facets 21 are imaged into the object field 5 with the aid of the second facet mirror 22. The second facet mirror 22 is the last beam-shaping mirror or else, in fact, the last mirror for the illumination radiation 16 in the beam path upstream of the object field 5.

In a further embodiment, not shown, of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or else alternatively two or more mirrors, which are arranged one behind the other in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20 and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is, as a rule, only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are similarly possible. The penultimate mirror M5 and the last mirror M6 each have a through opening for the illumination radiation 16. The projection optical unit 10 is a double-obscured optical unit. The projection optical unit 10 has an image-side numerical aperture which is greater than 0.5 and which can also be greater than 0.6 and, for example, be 0.7 or 0.75.

Reflection surfaces of the mirrors Mi can be embodied as free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a centre of the object field 5 and a y-coordinate of the centre of the image field 11. In the y-direction, this object-image offset can be of approximately the same magnitude as a z-distance between the object plane 6 and the image plane 12.

In particular, the projection optical unit 10 can have an anamorphic form. In particular, it has different imaging scales βx, βy in the x- and y-directions. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, that is to say in a direction perpendicular to the scanning direction.

The projection optical unit 10 leads to a reduction in size of 8:1 in the y-direction, that is to say in the scanning direction.

Other imaging scales are similarly possible. Imaging scales with the same sign and the same absolute value in the x-direction and y-direction are also possible, for example with absolute values of 0.125 or of 0.25.

The number of intermediate image planes in the x-direction and in the y-direction in the beam path between the object field 5 and the image field 11 can be the same or, depending on the embodiment of the projection optical unit 10, can differ. Examples of projection optical units with different numbers of such intermediate images in the x- and y-directions are known from US 2018/0074303 A1.

In each case one of the pupil facets 23 is assigned to exactly one of the field facets 21 for forming in each case an illumination channel for illuminating the object field 5. In particular, this can yield illumination according to the Köhler principle. The far field is decomposed into a multiplicity of object fields 5 with the aid of the field facets 21. The field facets 21 produce a plurality of images of the intermediate focus on the pupil facets 23 respectively assigned thereto.

By way of respectively assigned pupil facets 23, the field facets 21 are imaged onto the reticle 7 in a manner superposed on one another for the purposes of illuminating the object field 5. The illumination of the object field 5 is in particular as homogeneous as possible. It can have a uniformity error of less than 2%. The field uniformity can be achieved by way of the superposition of different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting.

A likewise preferred pupil uniformity in the region of sections of an illumination pupil of the illumination optical unit 4 which are illuminated in a defined manner can be achieved by a redistribution of the illumination channels.

Further aspects and details of the illumination of the object field 5 and in particular of the entrance pupil of the projection optical unit 10 are described below.

In particular, the projection optical unit 10 can have a homocentric entrance pupil. The latter can be accessible. It can also be inaccessible.

The entrance pupil of the projection optical unit 10 cannot, as a rule, be exactly illuminated using the pupil facet mirror 22. In the case of imaging of the projection optical unit 10 which telecentrically images the centre of the pupil facet mirror 22 onto the wafer 13, the aperture rays often do not intersect at a single point. However, it is possible to find an area in which the distance of the aperture rays determined in pairs becomes minimal. This area represents the entrance pupil or an area in real space that is conjugate thereto. In particular, this area has a finite curvature.

It may be the case that the projection optical unit 10 has different positions of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different positions of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged in tilted fashion with respect to the object plane 6. The first facet mirror 20 is arranged in tilted fashion with respect to an arrangement plane defined by the deflection mirror 19.

The first facet mirror 20 is arranged in tilted fashion with respect to an arrangement plane defined by the second facet mirror 22.

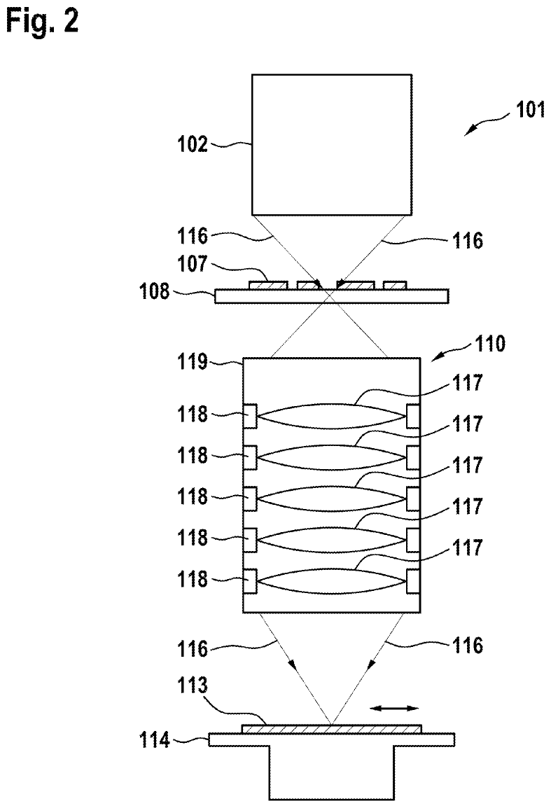

FIG. 2 schematically shows, in a meridional section, a further projection exposure apparatus 101 for DUV projection lithography, in which the disclosure can likewise be used.

The construction of the projection exposure apparatus 101 and the principle of the imaging are comparable with the construction and procedure described in FIG. 1. Identical component parts are designated by a reference sign increased by 100 relative to FIG. 1, i.e. the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, used as used light, in the range from 100 nm to 300 nm, in particular of 193 nm. The projection exposure apparatus 101 in this case substantially comprises an illumination system 102, a reticle holder 108 for receiving and exactly positioning a reticle 107 provided with a structure, by which the later structures on a wafer 113 are determined, a wafer holder 114 for holding, moving and exactly positioning the wafer 113 and a projection lens 110, with a plurality of optical elements 117, which are held by way of mounts 118 in a lens housing 119 of the projection lens 110.

The illumination system 102 provides DUV radiation 116, which is used for the imaging of the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the construction of the downstream projection optical unit 110 with the lens housing 119 does not differ in principle from the construction described in FIG. 1 and is therefore not described in further detail.

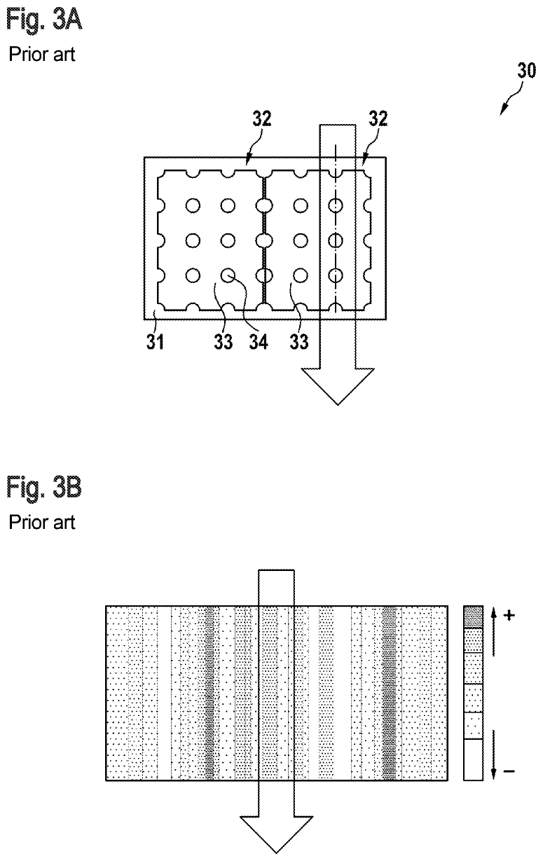

FIG. 3A shows a component 30 known from the prior art, which comprises a mirror 31 and two actuators in the form of actuator matrices 32. The actuator matrices 32 are arranged one next to the other on the rear side of the mirror 31 located opposite the optically effective surface (not illustrated) of the mirror 31. Each actuator matrix 32 has a plurality of square actuator pads 33, which are arranged in rows and columns and, at their corners, have holes 34 for contacting the actuator pads 33 with a controller (not illustrated). The plate-shaped actuator matrices 32 are rectangular, wherein two of the four peripheries of the actuator matrices 32 extend in the scanning direction, which is illustrated in FIG. 3A by a broad arrow. The holes 34 between the actuator pads 33 are located respectively one behind the other on an axis (indicated by a dashed line) extending parallel to the scanning direction. The parasitic deformations occurring are summed in the scanning direction and cause aberrations. The actuator matrices 32 can in principle also have a curved shape. The number of the actuator matrices 32 arranged on a mirror 31 is freely selectable, which is to say three, four or more actuator matrices 32 can also be formed on a mirror 31. In the same way, the number of rows and columns of the actuator matrices 32 is also freely selectable. Components 30 can thus also comprise on the mirror 31, in addition to the embodiment explained in FIG. 3A with two actuator matrices 32 with four rows and three columns, three actuator matrices 32 with five rows and five columns, or four matrices 32 with four rows and five columns or any other combination. The number of actuator matrices 32 and rows and columns is here predominantly dependent on the application and the producibility of the actuator matrices 32.

FIG. 3B shows an illustration of the parasitic aberration summed over the scanning operation. These are caused by parasitic deformations due to peripheral effects of the actuator matrices 32 based on losses in rigidity. The point densities used in the figure here correspond to wavefront deviations in a positive or negative direction. Clearly visible are the aberrations, aligned in the scanning direction illustrated in FIG. 3B by a broad arrow, in the form of regions of identical point densities extending in the scanning direction.

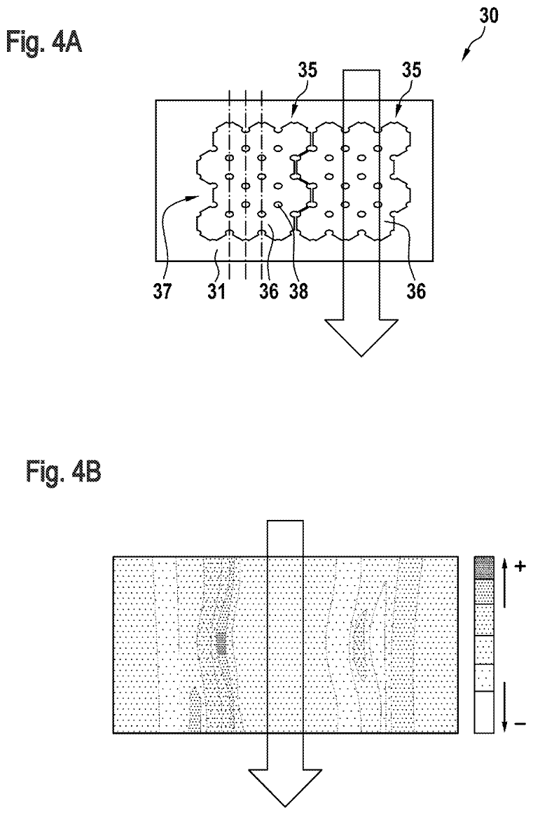

FIG. 4A shows a component 30 according to the disclosure, which comprises a mirror 31 and, arranged one next to the other, two actuators in the form of actuator matrices 35. Each actuator matrix 35 has actuator pads 36 having a hexagonal shape, which likewise have holes 38 at the corners for contacting the actuator pads 36 with a controller (not illustrated). The holes 38 are oval, wherein the longitudinal axis of the holes 38 is in each case aligned perpendicular to the scanning direction. The actuator pads 36 are arranged in rows 37 perpendicular to the scanning direction, which is illustrated in FIG. 4A by a broad arrow. The rows 37 are likewise arranged perpendicular to the scanning direction, in each case arranged in alternation offset from one another by half the width of an actuator pad. This results in a peripheral contour meandering around the scanning direction at the peripheries of the actuator matrix 35 that are located parallel to the scanning direction. The parasitic deformations brought about at the peripheral contour due to the losses in rigidity are thus advantageously averaged out by the scanning operation, and the resulting aberration is thus minimized. In addition to the adaptation of the peripheral contour with respect to the scanning direction, the narrower transverse axis of the oval holes 38 for contacting the actuator pads 36 is smaller than the diameter of the holes illustrated in FIG. 3A, as a result of which the cumulative length of the edge sections of the holes 38 extending parallel to the scanning direction is reduced. Furthermore, the holes 38 on a plurality of axes, which are illustrated in FIG. 4A as dash-dotted lines, are arranged parallel to the scanning direction due to the hexagonal shape of the actuator pads 36, as a result of which a smaller parasitic sum error is obtained per axis. As a result, the amplitude of the aberrations is advantageously minimized. In order to keep the distance between the adjacent actuator matrices 35 as small as possible, the actuator matrices 35 are arranged in intermeshed fashion. Consequently, the deformation effect of the actuator pads 36 over the abutting edges of two adjacent actuator matrices 35 is comparable to the actuator matrices 32 that are known from the prior art and have been explained in FIG. 3A. As was already explained with respect to FIG. 3A, the actuator matrices 32 can in principle also have a curved shape. Furthermore, the number of the actuator matrices 32 arranged on a mirror 31 is freely selectable, which is to say three, four or more actuator matrices 32 can also be formed on a mirror 31. In the same way, the number of rows and columns of the actuator matrices 32 is also freely selectable. Components 30 can thus also comprise on the mirror 31, in addition to the embodiment explained in FIG. 4A with two actuator matrices 32 with four rows and three columns, three actuator matrices 32 with five rows and five columns, or four matrices 32 with four rows and five columns or any other combination. The number of actuator matrices 32 and rows and columns is here predominantly dependent on the application and the producibility of the actuator matrices 32.

In comparison with the illustration of the parasitic aberrations explained in FIG. 3B, FIG. 4B shows a discernible reduction in the parasitic aberration summed by the scanning operation; which is discernible, firstly, by a reduction in the average absolute value of the point densities and, secondly, by a deviation of the profile of the regions of identical point densities and thus identical aberrations from the scanning direction.

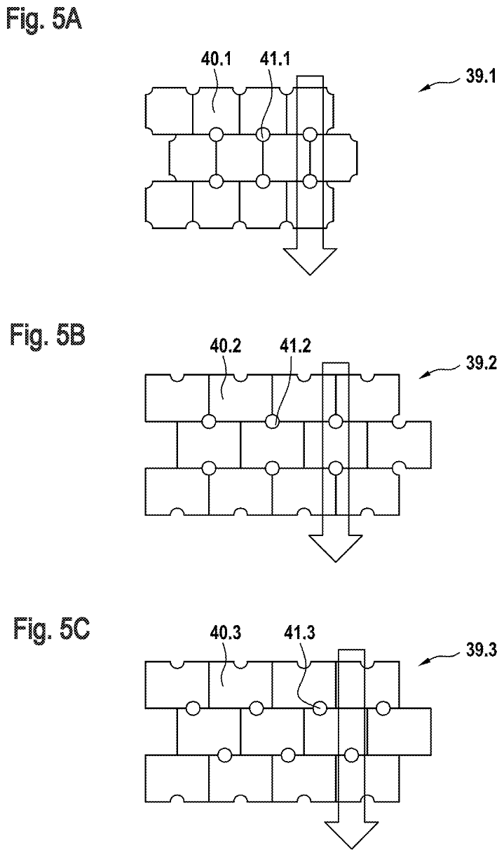

FIGS. 5A to 5F show further alternative embodiments of an actuator matrix 39.1, 39.2, 39.3, 39.4, 39.5, 39.6, which have different geometries of the actuator pads 40.1, 40.2, 40.3, 40.4, 40.5, 40.6 and different arrangements of the holes 41.1, 41.2, 41.3, 41.4, 41.5, 41.6 for contacting. The different combinations of the geometry of the actuator pads 40.1, 40.2, 40.3, 40.4, 40.5, 40.6 and of the shape and the arrangement of the holes 41.1, 41.2, 41.3, 41.4, 41.5, 41.6 are illustrated below in a table. The scanning direction is illustrated in the figures by an arrow.

| | Actuator pad | | Reference |
|---|---|---|---|
| FIG. | geometry | Hole geometry and arrangement | signs |
| 5A | square | round; in the corners | 40.1, 41.1 |
| 5B | rectangular | round; at the edges and corners | 40.2, 41.2 |
| 5C | rectangular | round; in the corners and at the edges | 40.3, 41.3 |
| 5D | triangular | round; in the centre | 40.4, 41.4 |
| 5E | triangular | oval; in alternation at the periphery | 40.5, 41.5 |
| 5F | square | oval; at an angle with respect to | 40.6, 41.6 |
| | | the scanning direction | |

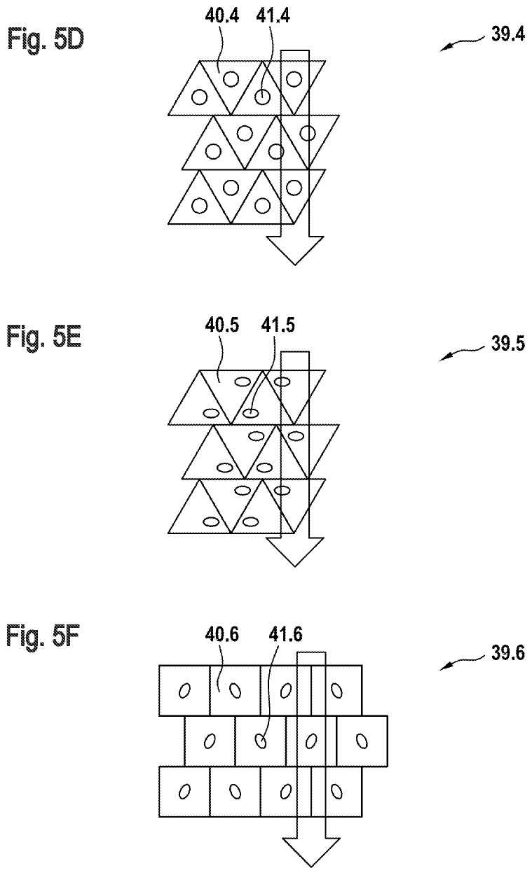

FIG. 6 shows a further embodiment of the disclosure illustrating a component 30 having a mirror 31 and three actuator matrices 43. As has already been described further above, the parasitic deformation brought about by losses in rigidity in the peripheral region of the actuator matrix 43 is minimized by the scanning operation if the peripheral length of the actuator matrix 43 that lies on an axis that is aligned parallel to the scanning direction is minimized. In the exemplary embodiment illustrated in FIG. 6, the entire periphery is aligned not parallel to the scanning direction owing to the trapezoidal shape of the actuator matrices 43, as a result of which the parasitic aberrations caused by the parasitic deformations present in the peripheral region can be avoided nearly completely or can be advantageously averaged out to a major extent by the scanning operation.

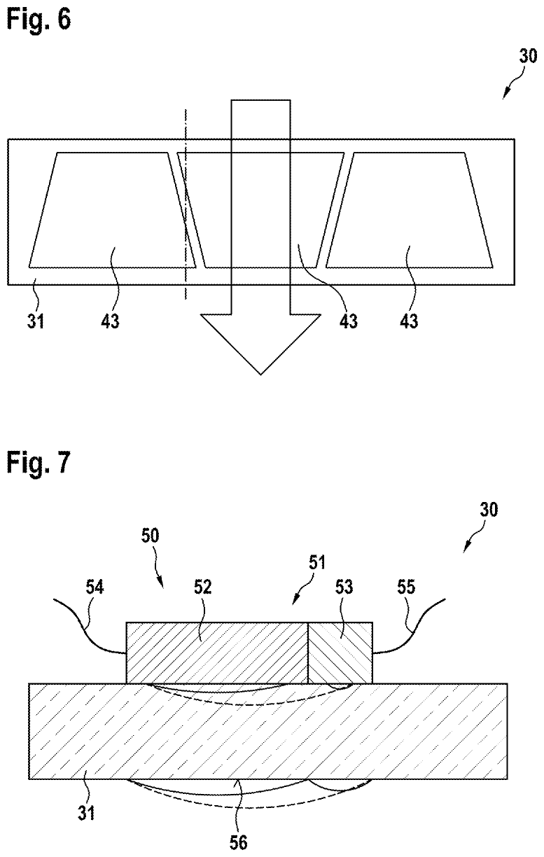

FIG. 7 shows a detail view of a component 30 with a mirror 31 and an actuator pad 51 arranged at the periphery of an actuator which is embodied in the form of an actuator matrix 50. The actuator pad 51 is divided into a partial actuator pad 52 and a peripheral actuator pad 53, which are controllable independently from one another via a respective line 54, 55. This has the advantage that the deformation of the optically effective surface 56 which is caused by the peripheral actuator pad 53 and is indicated by a solid line in FIG. 7 is greater in the peripheral region than the deformation which is caused by a non-divided actuator pad and is illustrated by a dashed line in FIG. 7. The parasitic deformations caused by the loss in rigidity in the peripheral region of the actuator matrix 50 are at least partially compensated thereby, as a result of which the parasitic aberrations are advantageously minimized.

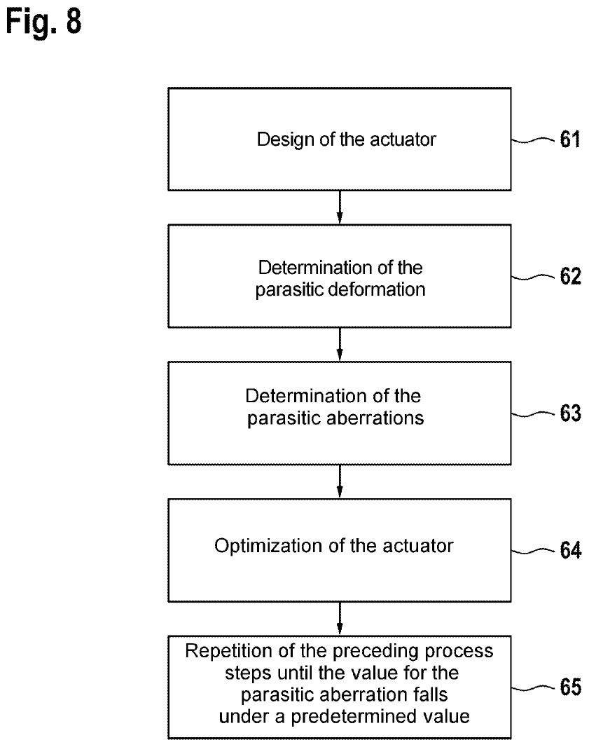

FIG. 8 describes a possible method for designing a component 30 of a projection exposure apparatus 1, 101 with an optical element 31 and an actuator 32, 35, 39.x, 43, 50 for minimizing the effects of parasitic deformations in the case of the deformation of the optical element 31 caused by the actuator 32, 35, 39.x, 43, 50 on the imaging quality of the projection exposure apparatus 1, 101.

The actuator 32, 35, 39.x, 43, 50 is designed in a first method step 61.

In a second method step 62, the parasitic deformations of the optical element 31 caused by an actuation or by different coefficients of thermal expansion of the optical element 31 and the actuator 32, 35, 39.x, 43, 50 are determined.

In a third method step 63, the parasitic aberrations are determined on the basis of the parasitic deformations while taking into account the summing effect of a scanning exposure used in the projection exposure apparatus.

In a fourth method step 64, the actuator is optimized on the basis of the determined parasitic aberrations. In this case, in particular the shape and arrangement of the individual actuator pads and of the holes can be varied.

In a fifth method step 65, at least some of the preceding process steps are repeated until the value for the parasitic aberration falls under a predetermined value.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Component
31 Mirror
32 Actuator matrix
33 Actuator pad
34 Holes
35 Actuator matrix
36 Actuator pad
37 Row
38 Holes
39.1-39.6 Actuator matrix
40.1-40.6 Actuator pad
41.1-41.6 Holes
42 Electrode
43 Actuator matrix
50 Actuator matrix
51 Actuator pad
52 Partial actuator pad
53 Peripheral actuator pad
54 Line
55 Line
56 Optically effective surface
61 Method step 1
62 Method step 2
63 Method step 3
64 Method step 4
65 Method step 5
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing

What is claimed is:

1. An apparatus, comprising:
a projection objective, comprising:
a component which comprises an optical element and an actuator,
wherein:
the optical element and the actuator are force-fittingly connected with each other;
the actuator is configured to at least locally deform the optical element;
the actuator is configured to reduce an influence of a loss in rigidity at peripheries delimiting the actuator on an imaging quality of the projection exposure apparatus; and
the apparatus is a projection exposure apparatus.

2. The apparatus of claim 1, wherein the actuator comprise an actuator matrix which comprises two actuator pads.

3. The apparatus of claim 2, wherein the actuator matrix comprises holes configured to contact the actuator pads, and the holes are configured to reduce a cumulative length of edge sections of the holes extending on an axis parallel to a scanning direction of the apparatus.

4. The apparatus of claim 3, wherein at least some of the holes have a minimal area.

5. The apparatus of claim 3, wherein the actuator matrix has a reduced number of holes on an axis extending parallel to the scanning direction.

6. The apparatus of claim 3, wherein the actuator pads have a triangular, a rectangular or a hexagonal geometry.

7. The apparatus of claim 1, wherein the apparatus has a minimal cumulative length of peripheral sections of the actuator extending on an axis parallel to a scanning direction of the apparatus.

8. The apparatus of claim 7, wherein outer peripheries of the actuators are aligned, at least in sections, at an angle to a scanning direction of the apparatus.

9. The apparatus of claim 7, wherein the actuator comprises a peripheral contour meandering around the scanning direction of the apparatus.

10. The apparatus of claim 7, wherein a straight peripheral structure of the actuator is aligned at an angle to the scanning direction of the apparatus.

11. The apparatus of claim 1, wherein the actuator comprises a separately controllable section configured to correct loss of rigidity.

12. The apparatus of claim 11, wherein the section is formed as a peripheral actuator pad in an actuator pad in the peripheral region of the actuator matrix and is controllable independently of the second region of the actuator pad formed as a partial actuator pad and is configured for correcting the parasitic deformations caused by the loss in rigidity.

13. The apparatus of claim 11, wherein the actuator matrix comprises holes configured to contact the actuator pads, and the holes are configured to reduce a cumulative length of edge sections of the holes extending on an axis parallel to a scanning direction of the apparatus.

14. The apparatus of claim 11, wherein the apparatus has a minimal cumulative length of peripheral sections of the actuator extending on an axis parallel to a scanning direction of the apparatus.

15. The apparatus of claim 1, wherein the actuator comprise an actuator matrix which comprises two actuator pads, and the apparatus has a minimal cumulative length of peripheral sections of the actuator extending on an axis parallel to a scanning direction of the apparatus.

16. A method of designing a component of a projection exposure apparatus comprising an optical element and an actuator to reduce effects of parasitic deformations on imaging quality of the projection exposure apparatus due to the actuator deforming the optical element, the method comprising:
designing the actuator;
determining the parasitic deformations of the optical element caused by an actuation or by different coefficients of thermal expansion of the optical element and the actuator;
determining parasitic aberrations based on the parasitic deformations while taking into account a summing effect of a scanning exposure used in the projection exposure apparatus;
improving the actuator based on the determined parasitic aberrations; and
repeating at least some of the preceding process steps until a value for the parasitic aberration falls is less than a predetermined value.

17. The method of claim 16, further comprising using at least a part of a travel of the actuator to correct the parasitic deformations.

18. The method of claim 16, wherein:
the projection exposure apparatus comprises a mechanism configured to improve the imaging quality of the projection exposure apparatus; and
the method further comprises taking the mechanism into account when determining the parasitic aberrations.

19. The method of claim 18, wherein the mechanism comprises manipulators configured to position or deform further optical elements of the projection exposure apparatus.

20. The method of claim 18, wherein the mechanism comprises an algorithm based on simulations for predicting the imaging quality of the projection exposure apparatus while taking into account a multiplicity of influence parameters and a determination of travels of manipulators therefor.
